(19) United States
(12) Patent Application Publication
(10) Pub. No.: US 2010/0231775 A1
(43) Pub. Date: Sep. 16, 2010

(54) SOLID-STATE IMAGING ELEMENT AND MANUFACTURING METHOD THEREOF

(75) Inventors: Noriaki SUZUKI, Kyoto (JP); Ikuo MIZUNO, Kyoto (JP); Mitsuyoshi ANDOU, Toyama (JP)

Correspondence Address: GREENBLUM & BERNSTEIN, P.L.C., 1950 ROLAND CLARKE PLACE, RESTON, VA, 20191, US

(73) Assignee: Panasonic Corporation, Osaka (JP)

(21) Appl. No.: 12/719,909

(22) Filed: Mar. 9, 2010

(30) Foreign Application Priority Data
Mar. 12, 2009 (JP) 2009-060263

(51) Int. Cl. H04N 5/335; H01L 31/18

(52) U.S. Cl. 348/311; 438/60; 257/E31.097; 348/E05.091

(57) ABSTRACT

A solid-state imaging element having high sensitivity and low smear in miniaturization is provided. The solid-state imaging element includes: a photoelectric conversion unit; a read-out unit; a charge transferring unit; a charge transfer electrode formed over the charge transferring unit; shielding film formed over the charge transfer electrode and has an opening part over the photoelectric conversion unit; and anti-reflection film formed (i) in the opening part, and (ii) over the charge transfer electrode. A first edge, of the to anti-reflection film formed in the opening part, stops protruding before reaching spacing found under the shielding film. A second edge, of the anti-reflection film formed over the charge transfer electrode, stops protruding before covering a side wall of the charge transfer electrode. The first edge faces the side wall of the charge transfer electrode, and the second edge protrudes in a read-out direction of the charge.

### BACKGROUND OF THE INVENTION

(1) Field of the Invention

The present invention relates to a solid-state imaging element and a manufacturing method thereof, in particular, to a structure of anti-reflection film.

(2) Description of the Related Art

More and more solid-state imaging elements are equipped with mega pixels, as well as having miniaturized pixels in dimension. In order to improve sensitivity of the solid-state imaging elements, proposed is a structure to have high-refractive film formed over a photoelectric conversion unit, the high-refractive film which prevents reflection (See Patent Reference 1: Japanese Patent No. 3204216 for reference).

FIG. 14 exemplified a cross-section of a conventional solid-state imaging element. Formed on a silicon substrate 1 are a photodiode (photoelectric conversion unit) 2, a read-out area 3, a column transfer unit (a transfer area) 4, and a non read-out area 5. Formed over the silicon substrate 1 via gate dielectric film 6 is a charge transfer electrode 7. In an upper layer over the charge transfer electrode 7, formed via dielectric film is an anti-reflection film 8, such as silicon nitride film. In an upper layer over the anti-reflection film 8, formed is shielding film 10 having an opening part over a light-receiving area. In order to reduce a dark current, a part of the anti-reflection film 8 is removed. Here, the removed part lies over the charge transfer electrode 7. Then, hydrogen is fed for sintering.

In the exemplified structure of the conventional solid-state imaging element, however, a smaller pixel dimension due to prospective further miniaturization will end in having the anti-reflection film 8 laid between (i) an edge of the shielding film 10 over a side wall of the charge transfer electrode 7 and (ii) the silicon substrate 1. This lying anti-reflection film 8 will cause the film thickness great between the edge of the shielding film 10 and the silicon substrate 1. Accordingly, the conventional solid-state imaging element has a problem in that obliquely incident light entering at the opening part between the shielding film 10 and the silicon substrate 1 results in developing further smear. The lying anti-reflection film 8 will also make the film thickness great between (i) the shielding film 10 covering the side wall over the charge transfer electrode 7 and (ii) the side wall over the charge transfer electrode 7. This will narrow the opening part area which defines the width of a light-receiving area. Hence, the conventional solid-state imaging element faces a problem of decreasing sensitivity.

In addition, the further miniaturization will make a pixel smaller in dimension. This will develop a problem in the conventional solid-state imaging element in that it is process-wise difficult to partially remove the anti-reflection film 8 lying over the charge transfer electrode 7.

### SUMMARY OF THE INVENTION

The present invention is conceived in view of the above problems and has as an object to provide a solid-state imaging element and a manufacturing method thereof, the solid-state imaging element which has high sensitivity and low smear without complex processing in miniaturization, such as partially removing anti-reflection film lying over a charge transfer electrode.

In order to achieve the above object, an aspect of a solid state imaging element in accordance with the present invention includes: a photoelectric conversion unit; a read-out area to which charge from the photoelectric conversion unit is read out; a charge transferring unit which transfers the read-out charge; a charge transfer electrode which is formed over the charge transferring unit; shielding film which is formed over the charge transfer electrode and has an opening part over the photoelectric conversion unit; and anti-reflection film formed (i) in the opening part, and (ii) over the charge transfer electrode, wherein the photoelectric conversion unit, the read-out area, and the charge transferring unit are formed on a substrate, and (i) a first edge, of the anti-reflection film which is formed in the opening part, stops protruding before reaching spacing found under the shielding film, and (ii) a second edge, of the anti-reflection film which is formed over the charge transfer electrode, stops protruding before covering a side wall of the charge transfer electrode, the first edge facing the side wall of the charge transfer electrode and the second edge protruding in a read-out direction of the charge.

The above structure enables the anti-reflection film to be formed with a part over the photoelectric conversion unit and a part over the charge transfer electrode separated, instead of being formed in continuous sheeting. This allows the anti-reflection film to avoid protruding between (i) an edge of the shielding film covering the side wall of the charge transfer electrode, and (ii) the silicon substrate. This structure makes possible reducing: the film thickness between the edge of the shielding film and the silicon substrate; and obliquely incident light entering at the spacing between the edge and the silicon substrate. This solves a conventional problem of developing further smear. Further, with a use of the above structure, the film thickness becomes thinner between (i) the edge of the shielding film covering the side wall of the charge transfer electrode, and (ii) the side wall of the charge transfer electrode. This prevents the opening part area, which defines the light-receiving area, from being smaller, and solves the problem of decreasing sensitivity. Accordingly, high sensitivity and low smear is realized in pursuing further miniaturization in pixel dimension.

In addition, the anti-reflection film is formed with the part over the photoelectric conversion unit and the part over the charge transfer electrode separated. Via the separated portion, the hydrogen sent from outside by sintering can easily arrive at the photodiode. This makes possible eliminating the need for a conventional technique; that is, removing a part of the anti-reflection film lying over the charge transfer electrode. In other words, this structure can reduce the dark current without complex processing.

In the above structure of an aspect of the solid state imaging element in accordance with the present invention, the distance between the first edge and the second edge is preferably 0.20 μm to 0.50 μm.

This makes possible enlarging the areas: over the photoelectric conversion unit; and of the anti-reflection film lying over the charge transfer electrode, and provides a solid-state imaging element which has high sensitivity and low smear. Further, the larger area of the anti-reflection film lying over the charge transfer electrode can slow reduction of the voltage tolerance, against the shielding film, over the charge transfer electrode. In particular, the above structure is effective since the thickness of the dielectric film can be locally-reduced with ease in spacing lying between electrodes in the case where the charge transfer electrode is in a single layer structure. The above structure is also effective in the case where the shielding film is used for shunt wiring since 12V and −6V are respectively applied to the charge transfer electrode and the shielding film, and thus a high field is created.

In the above structure of an aspect of the solid state imaging element in accordance with the present invention, silicon-based dielectric film is preferably laminated on the anti-reflection film formed over the charge transfer electrode.

This structure makes possible adjusting the distance between the silicon substrate and the shielding film which lies over the charge transfer electrode in order to obtain a downwardly-protruding in-layer lens in any desired form.

Moreover, an aspect of a method for manufacturing a solid-state imaging element in accordance with the present invention includes: forming anti-reflection film over the photoelectric conversion unit and the charge transfer electrode; and forming shielding film over the anti-reflection film, wherein the forming shielding film involves forming an opening part on the shielding film lying over the photoelectric conversion unit, and in the forming anti-reflection film, (i) a first edge, of the anti-reflection film which is formed over the photoelectric conversion unit, stops protruding before reaching spacing found under the shielding film, and (ii) a second edge, of the anti-reflection film which is formed over the charge transfer electrode, stops protruding before covering a side wall of the charge transfer electrode, the first edge facing the side wall of the charge transfer electrode, and the second edge protruding in read-out direction of the charge. Here, the solid-state imaging element in accordance with the present invention may have: a photoelectric conversion unit; a read-out area to which charge from the photoelectric conversion unit is read out; a charge transferring unit which transfers the read-out charge; and a charge transfer electrode which is formed over the charge transferring unit, the photoelectric conversion unit, the read-out area, and the charge transferring unit being formed on a substrate.

This structure can solve a problem of developing further smear due to obliquely incident light, as well as a problem of a decreasing opening part area which defines the light-receiving area. Accordingly, high sensitivity and low smear is realized in pursuing further miniaturization in pixel dimension.

Furthermore, in an aspect of the method for manufacturing the solid-state imaging element in accordance with the present invention, the forming of the anti-reflection film may involve repeatedly patterning the anti-reflection film.

This structure allows the anti-reflection film to be fine-patterned with ease. In addition, each patterning may separately involve patterning the anti-reflection film provided over (i) the photoelectric conversion unit, and (ii) the charge transfer electrode, for example. This patterning makes possible patterning the anti-reflection film with an appropriate focus for each patterning.

Moreover, in an aspect of the method for manufacturing the solid-state imaging element in accordance with the present invention, the forming the anti-reflection film may involve the patterning with a use of partial hard mask including silicon-based dielectric film.

This structure allows the anti-reflection film to be easily fine-patterned. This also makes possible adjusting the distance between the silicon substrate and the shielding film which lies over the charge transfer electrode in order to obtain a downwardly-protruding in-layer lens in any desired form.

Furthermore, in an aspect of the method for manufacturing the solid-state imaging element in accordance with the present invention, the forming of the anti-reflection is carried out using a Low Pressure Chemical Vapor Deposition technique.

This technique eliminates the plasma induced damage in forming the anti-reflection film, which can reduce the dark current.

The solid-state imaging element of the present invention can achieve high sensitivity and low smear without complex processing in prospective further miniaturization, such as partially removing anti-reflection film lying over a charge transfer electrode.

Moreover, a method for manufacturing the solid-state imaging element of the present invention allows the anti-reflection film to be easily fine-patterned.

### FURTHER INFORMATION ABOUT TECHNICAL BACKGROUND TO THIS APPLICATION

The disclosure of Japanese Patent Application No. 2009-060263 filed on Mar. 12, 2009 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a schematic block diagram of a solid-state imaging element in accordance with an embodiment of the present invention;

FIG. 2 is a plan view of the solid-state imaging element in accordance with the embodiment of the present invention;

FIG. 3 is a first plan view of anti-reflection film in the solid-state imaging element in accordance with the embodiment of the present invention;

FIG. 4 is a second plan view of the anti-reflection film in the solid-state imaging element in accordance with the embodiment of the present invention;

FIG. 5 is a final plan view of the anti-reflection film in the solid-state imaging element in accordance with the embodiment of the present invention;

FIG. 6 is a plan view of shielding film in the solid-state imaging element in accordance with the embodiment of the present invention;

FIG. 7 shows a step in a manufacturing process of the solid-state imaging element in accordance with the embodiment of the present invention;

FIG. 8 shows a step in the manufacturing process of the solid-state imaging element in accordance with the embodiment of the present invention;

FIG. 9 shows a step in the manufacturing process of the solid-state imaging element in accordance with the embodiment of the present invention;

FIG. 10 shows a step in the manufacturing process of the solid-state imaging element in accordance with the embodiment of the present invention;

FIG. 11 shows a step in the manufacturing process of the solid-state imaging element in accordance with the embodiment of the present invention;

FIG. 12 shows a step in the manufacturing process of the solid-state imaging element in accordance with the embodiment of the present invention;

FIG. 13 shows a step in the manufacturing process of the solid-state imaging element in accordance with the embodiment of the present invention; and

FIG. 14 is a schematic block diagram of a conventional solid-state imaging element.

### DESCRIPTION OF THE PREFERRED EMBODIMENT

Hereinafter, an embodiment of the present invention shall be described with reference to the drawings.

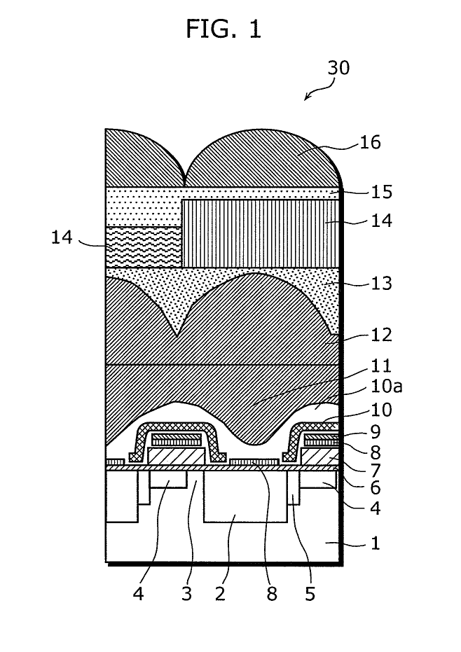

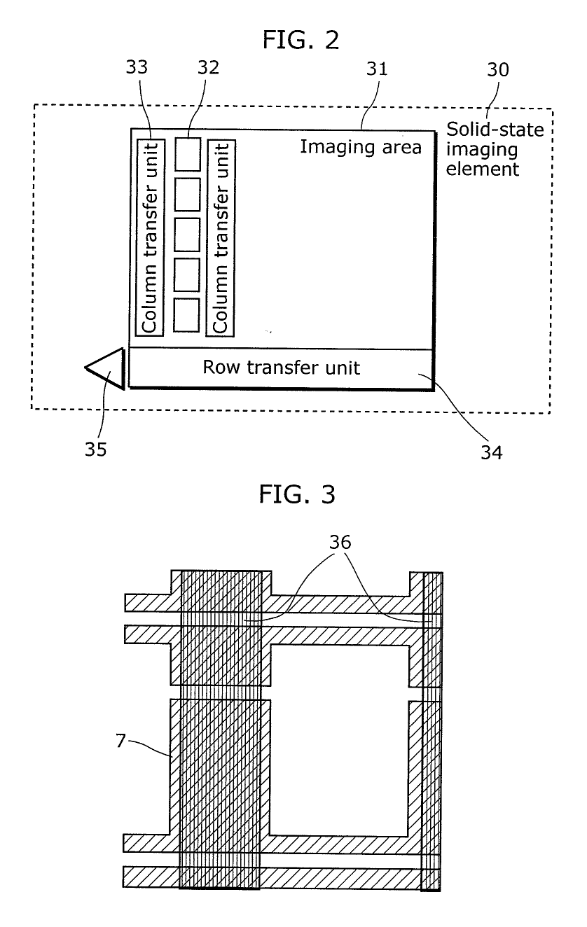

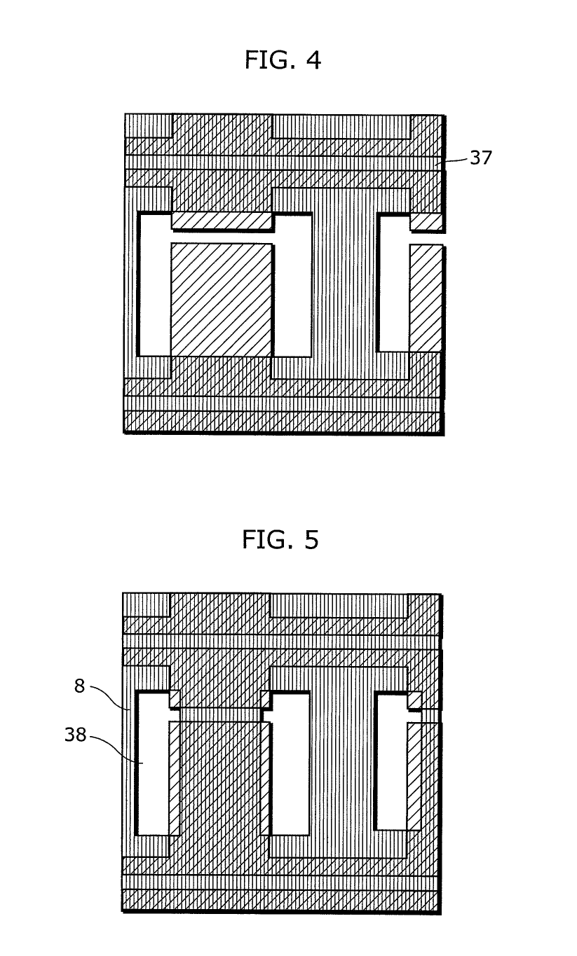

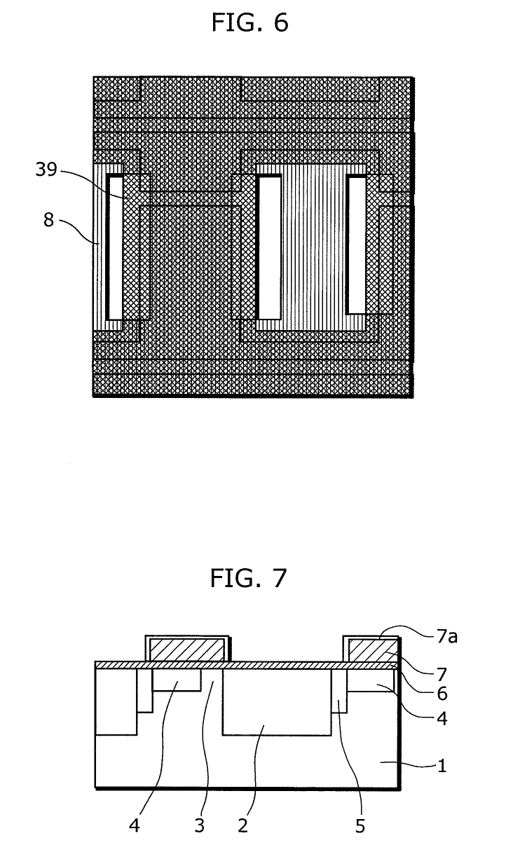

FIG. 1 is a schematic block diagram of a solid-state imaging element 30 in accordance with an embodiment of the present invention. FIG. 2 is a plan view of the solid-state imaging element 30. FIGS. 3 and 4 show layouts for patterning an anti-reflection film in twice. FIG. 5 shows a layout of the resulting anti-reflection film. FIG. 6 shows a layout of shielding film.

According to FIG. 1, a photodiode (photoelectric conversion unit) 2, a read-out area 3, a column transfer unit (transfer area) 4, a non read-out area 5 are formed on an Si substrate 1. Formed over the column transfer unit (charge transferring unit) 4 in the Si substrate 1 and via a gate dielectric film 6 is a charge transfer electrode 7. A shielding film 10 is formed to cover the charge transfer electrode 7. An anti-reflection film 8 is formed in an opening part (over the photoelectric conversion unit) of the shielding film 10 and over the charge transfer electrode 7. Over the charge transfer electrode 7, formed in the spacing between the anti-reflection film 8 and the shielding film 10 is silicon-based dielectric film 9. It is noted that laminated on the shielding film 10 are passivation film 10a, a downwardly-protruding in-layer lens 11, an upwardly-protruding in-layer lens 12, planarizing film 13, a color filter 14, planarizing film 15, and a microlens 16.

The solid-state imaging element 30 has the characteristics below. The shielding film 10 is formed over the charge transfer electrode 7, and has the opening part over the photodiode 2. The anti-reflection film 8 is formed: in the opening part provided over the photodiode 2; and over the charge transfer electrode 7. Facing the side wall of the charge transfer electrode 7, a first edge, of the anti-reflection film 8 which is formed in the opening part, stops protruding before reaching the spacing found under the shielding film 10. A second edge of the anti-reflection film 8 stops protruding before covering the side wall of the charge transfer electrode 7. Here, the second edge protrudes in a read-out direction of the charge which is read out from the photoelectric conversion unit.

As shown in FIG. 2, the solid-state imaging element 30 planarily has: an imaging area 31 on which column transfer units 33 (the column transfer unit 4 in FIG. 1), and photodiodes 32 (the photodiode 2 in FIG. 1) are alternatively arranged; a row transfer unit 34 which transfers the charge provided from the column transfer unit 4 in a row direction; and an output amplifier 35 which outputs the charge transferred from the row transfer unit 34 in a form of charge.

Described below is the reason why the solid-state imaging element 30 in accordance with the embodiment structured above is effective against the smear and in improving sensitivity.

Instead of being formed in continuous sheeting including a part over the photoelectric conversion unit (the photodiode 2) and a part over the charge transfer electrode 7, the anti-reflection film 8 is formed with the both parts separated (planarily, the opening part disposed). This allows the anti-reflection film 8 to avoid protruding between (i) an edge of the shielding film 10 covering the side wall of the charge transfer electrode 7 and (ii) the silicon substrate 1 (the photodiode 2 and the non read-out area 5 in FIG. 1). This structure makes possible reducing the film thickness between the edge of the shielding film 10 and the silicon substrate 1, and curbing the development of smear due to the obliquely incident light entering at the spacing between the edge and the silicon substrate 1. In addition, the anti-reflection film 8 is not formed between (i) the shielding film 10 covering the side wall of the charge transfer electrode 7 and (ii) the side wall of the charge transfer electrode 7. Since the film thickness becomes thinner between (i) the shielding film 10 covering the side wall of the charge transfer electrode 7 and (ii) the side wall of the charge transfer electrode 7 due to the above structure, the resulting opening part area, which defines the light-receiving area, can be enlarged by 0.1 μm in width. This can improve the sensitivity.

In addition, an adjustment in (i) dimensions of the anti-reflection film 8 lying over the charge transfer electrode 7, and (ii) film thickness of the silicon-based dielectric film 9 laminated on the anti-reflection film 8 makes possible adjusting the film thickness between the charge transfer electrode 7 and the shielding film 10. Since this enables the downwardly-protruding in-layer lens 11 to be formed in any desired form, a most suitable lens can be easily produced.

Moreover, the anti-reflection film 8 is formed in the opening part, with spacing provided. Via the spacing, the hydrogen sent from outside by sintering can easily arrive at the photodiode 2, which makes possible reducing the dark current. In other words, the dark current can be reduced without conventional complex processing, such as partially removing anti-reflection film lying over a charge transfer electrode.

Described next is a manufacturing method of the solid-state imaging element 30 in accordance with the embodiment of the present invention, with reference to FIGS. 7 to 13.

FIG. 7 shows the forming of (i) the charge transfer electrode 7 over the top surface of the silicon substrate 1 via the gate dielectric film 6 made of silicon oxide, and (ii) dielectric film 7a over the charge transfer electrode 7. Here, the gate dielectric film 6 on the photoelectric conversion unit (the photodiode 2) is preferably 10 to 100 nm in film thickness, more preferably approximately 25 nm.

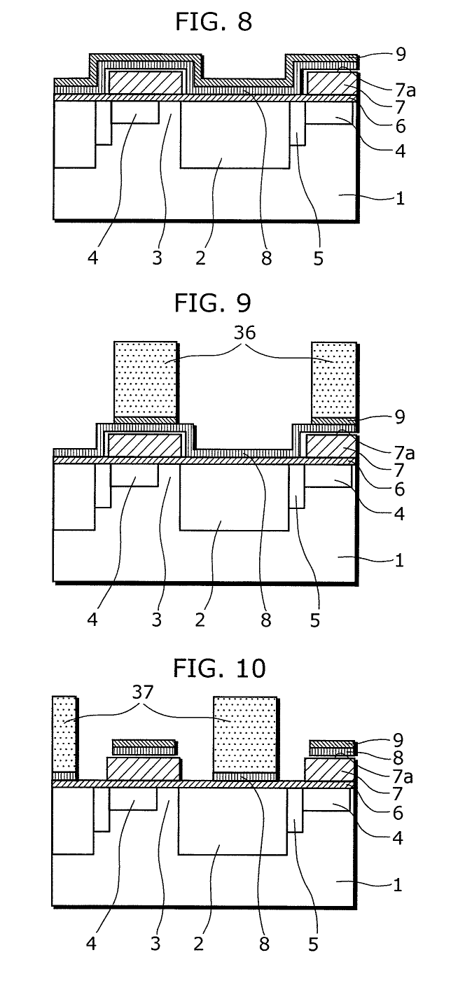

Then, as shown in FIG. 8, the anti-reflection film 8 and the silicon-based dielectric film 9 respectively made of silicon nitride and silicon oxide is formed. The anti-reflection film 8 is preferably 30 to 100 nm in film thickness, more preferably approximately 50 nm.

The silicon-based dielectric film 9 is preferably 10 to 100 nm in film thickness, more preferably approximately 15 nm. Conventional techniques face difficulty forming the downwardly-protruding in-layer lens 11 having acute curvature. The present invention, meanwhile, enables the film thickness of the silicon-based dielectric film 9 to be adjusted, so that the downwardly-protruding in-layer lens 11 can be formed in any desired shape.

Next, as shown in FIG. 9, resist pattern 36 is formed (See FIG. 3 for the layout), and the silicon-based dielectric film 9 which lies over areas, other than the charge transfer electrode 7, is removed by, for example, wet etching.

Then, as shown in FIG. 10, resist pattern 37 is formed (See

FIG. 4 for the layout), and the anti-reflection film 8 is removed by etching. The etching is, for example, chemical dry etching which enjoys high selectivity with the silicon-based dielectric film 9, and is conducted with a use of mixed gas including CF (chlorotrifluoromethane) 4. Here, the anti-reflection film 8 over the charge transfer electrode 7 is protected by the silicon-based dielectric film 9. Thus, only the anti-reflection film 8 over the photoelectric conversion unit is removed. This step involves several times of patterning (twice in the embodiment) to form the anti-reflection film 8 having the layout shown in FIG. 5. As shown in FIG. 5, a part of the anti-reflection film 8, which lies near the boundary of the charge transfer electrode 7 and the photoelectric conversion unit (the photodiode 2), is removed to form an opening part 38. The length of the opening part 38 in the charge read-out direction (the distance between the first edge of the anti-reflection film 8 over the photoelectric conversion unit and the second edge of the anti-reflection film 8 over the charge transfer electrode 7) is, for example, 0.20 μm to 0.50 μm.

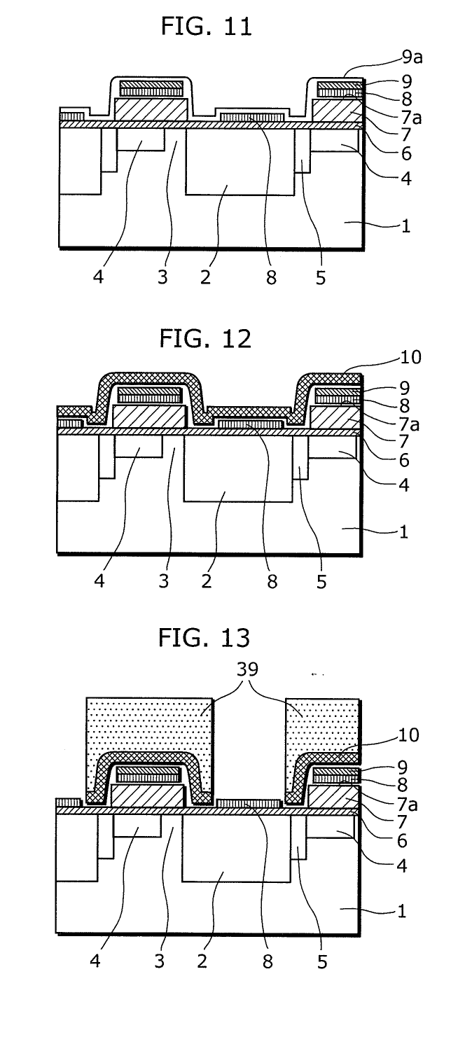

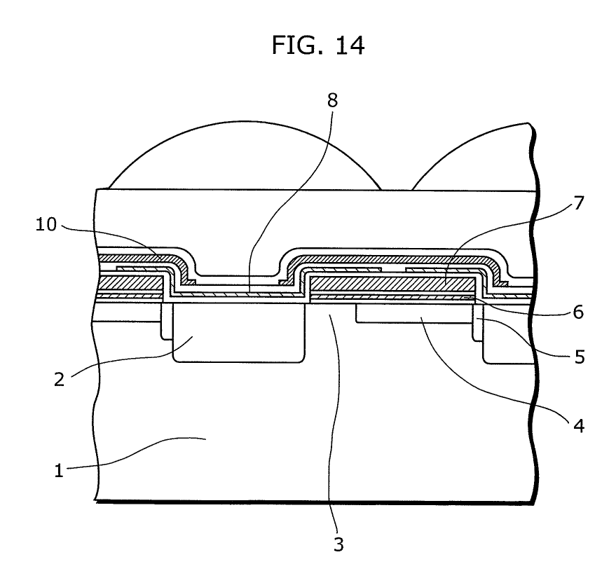

Next, as shown in FIG. 11, silicon oxide film 9a is formed. The silicon oxide film 9a is preferably 2 to 80 nm in film thickness, more preferably approximately 10 nm.

Then, as shown in FIG. 12, the shielding film 10 made of tungsten is formed. The shielding film 10 is preferably 80 to 300 nm in film thickness, more preferably approximately 100 nm.

Next, as shown in FIG. 13, resist pattern 39 is formed, and the shielding film 10 is removed by etching. As a result of the etching, formed is the shielding film 10 having the layout shown in FIG. 6.

Then, as shown in FIG. 1, the downwardly-protruding in-layer lens 11, the upwardly-protruding in-layer lens 12, the color filter 14, and the microlens 16 are formed. Here, the in-layer lenses 11 and 12 may be formed out of a single sheet of film in order to be formed in one piece. The in-layer lenses 11 and 12 can improve efficiency in light collection on photodiode 2. In addition, the solid-state imaging element of the present invention has the shielding film 10 formed near the Si substrate 1, which significantly prevents development of the smear due to the light refracted by the in-layer lenses 11 and 12.

According to the structure of the solid-state imaging element 30 in accordance with the embodiment, the anti-reflection film 8 is formed by patterning in twice (See the steps shown in FIGS. 9 and 10). This allows easy processing in small pixel dimensions due to the miniaturization. This also makes possible enlarging the areas: over the photoelectric conversion unit (the photodiode 2); and of the anti-reflection film 8 lying over the charge transfer electrode 7, which realizes high sensitivity and low smear. In addition, the charge transfer electrode 7 is covered with the anti-reflection film and the silicon-based dielectric film 9 both of which is partly un-removed. This makes possible slowing reduction of the voltage tolerance, against the shielding film 10, over the charge transfer electrode 7.

Moreover, the anti-reflection film 8 is formed in the opening part, with the spacing provided. Via the spacing, the hydrogen sent from outside by sintering can easily arrive at the photodiode 2, which makes possible reducing the dark current.

Although only an exemplary embodiment of this invention has been described in detail above, those skilled in the art will readily appreciate that many modifications are possible in the exemplary embodiment without materially departing from the novel teachings and advantages of this invention. Accordingly, all such modifications are intended to be included within the scope of this invention.

### INDUSTRIAL APPLICABILITY

The present invention realizes low smear and high sensitivity, and is effectively employed for solid-state imaging elements having miniaturized pixels. In particular, the present invention can be used for a CCD solid-state imaging element included in a digital camera and a cellular phone.

What is claimed is:

1. A solid-state imaging element comprising:
a photoelectric conversion unit;
a read-out area to which charge from said photoelectric conversion unit is read out;
a charge transferring unit configured to transfer the read-out charge;
a charge transfer electrode which is formed over said charge transferring unit;
shielding film which is formed over said charge transfer electrode and has an opening part over said photoelectric conversion unit; and
anti-reflection film formed (i) in the opening part, and (ii) over said charge transfer electrode, wherein said photoelectric conversion unit, said read-out area, and said charge transferring unit are formed on a substrate, and
(i) a first edge, of said anti-reflection film which is formed in the opening part, stops protruding before reaching spacing found under said shielding film, and (ii) a second edge, of said anti-reflection film which is formed over said charge transfer electrode, stops protruding before covering a side wall of said charge transfer electrode, the first edge facing the side wall of said charge transfer electrode and the second edge protruding in a read-out direction of the charge.

2. The solid-state imaging element according to claim 1,
wherein distance between the first edge and the second edge is 0.20 μm to 0.50 μm.

3. The solid-state imaging element according to claim 1,
wherein silicon-based dielectric film is laminated on said anti-reflection film formed over said charge transfer electrode.

4. A method for manufacturing a solid-state imaging element which has: a photoelectric conversion unit; a read-out area to which charge from the photoelectric conversion unit is read out; a charge transferring unit which transfers the read-out charge; and a charge transfer electrode which is formed over the charge transferring unit, the photoelectric conversion unit, the read-out area, and the charge transferring unit being formed on a substrate, and said method comprising:
forming anti-reflection film over the photoelectric conversion unit and the charge transfer electrode; and
forming shielding film over the anti-reflection film,
wherein said forming shielding film involves forming an opening part on the shielding film lying over the photoelectric conversion unit, and
in said forming anti-reflection film, (i) a first edge, of the anti-reflection film which is formed over the photoelectric conversion unit, stops protruding before reaching spacing found under the shielding film, and (ii) a second edge, of the anti-reflection film which is formed over the charge transfer electrode, stops protruding before covering a side wall of the charge transfer electrode, the first edge facing the side wall of the charge transfer electrode, and the second edge protruding in read-out direction of the charge.

5. The method for manufacturing the solid-state imaging element according to claim 4,
wherein said forming the anti-reflection film involves repeatedly patterning the anti-reflection film.

6. The method for manufacturing the solid-state imaging element according to claim 4,
wherein said forming the anti-reflection film involves the patterning with a use of partial hard mask including silicon-based dielectric film.

7. The method for manufacturing the solid-state imaging element according to claim 4,
wherein said forming the anti-reflection is carried out using a Low Pressure Chemical Vapor Deposition technique.
